(19) United States
(12) Patent Application Publication
(10) Pub. No.: US 2025/0336857 A1
(43) Pub. Date: Oct. 30, 2025

(54) Semiconductor Package

(71) Applicant: Samsung Electronics Co., Ltd., Suwon-si (KR)

(72) Inventor: Daehun Lee, Suwon-si (KR)

(21) Appl. No.: 18/887,211

(22) Filed: Sep. 17, 2024

(30) Foreign Application Priority Data
Apr. 26, 2024 (KR) 10-2024-0056030

(51) Int. Cl. H01L 23/00; H01L 23/31

(52) U.S. Cl. CPC H01L 24/06; H01L 23/3128; H01L 24/04; H01L 24/13; H01L 24/16; H01L 24/32; H01L 24/73; H01L 2224/0401; H01L 2224/06051; H01L 2224/13147; H01L 2224/16225; H01L 2224/32225; H01L 2224/73204; H01L 2924/1431

(57) ABSTRACT

A semiconductor package may include a package substrate including a center region and a peripheral region surrounding the center region, a bump pad including a first bump pad on the center region and a second bump pad on the peripheral region and having a planar shape different from that of the first bump pad, a semiconductor chip on the package substrate and including a solder bump electrically connected to the bump pad, and a masking member on the package substrate to cover at least a part of the bump pad, wherein the peripheral region includes an edge region in contact with each edge of the center region and corner regions positioned at both ends of the edge region, and the masking member is on the corner regions.

### CROSS-REFERENCE TO RELATED APPLICATION

This application claims priority to Korean Patent Application No. 10-2024-0056030, filed in the Korean Intellectual Property Office on Apr. 26, 2024, the entire contents of which are hereby incorporated by reference.

### FIELD

The present disclosure relates to a semiconductor package.

### BACKGROUND

A semiconductor package may electrically connect a semiconductor chip and a package substrate to each other. Accordingly, for the semiconductor package, it is important to ensure the mechanical and electrical reliability of the solder bumps, etc. that electrically connect the package substrate and the semiconductor chip to each other.

The solder bump may also be disposed on the package substrate to contact with the solder bump of the semiconductor chip, but solder bumps may be omitted from the package substrate to reduce cost.

Meanwhile, since the semiconductor package may include several materials with different coefficients of thermal expansion, warpage may occur in which the semiconductor package is bent or distorted, and this should be inhibited or prevented.

### SUMMARY

In order to solve one or more problems (e.g., the problems described above and/or other problems not explicitly described herein), the present disclosure provides a semiconductor package with improved mechanical and electrical reliability.

According to some embodiments of the present disclosure, a semiconductor package may include a package substrate including a center region and a peripheral region surrounding the center region, a bump pad including a first bump pad on the center region and a second bump pad on the peripheral region and having a planar shape different from that of the first bump pad, a semiconductor chip on the package substrate and including a solder bump electrically connected to the bump pad, and a masking member on the package substrate to cover at least a part of the bump pad, wherein the peripheral region includes an edge region in contact with each edge of the center region and corner regions positioned at both ends of the edge region, and the masking member is on the corner regions.

According to some embodiments of the present disclosure, a semiconductor package may include a package substrate including a center region, an edge region in contact with each edge of the center region, and a corner region at an end of the edge region, a bump pad including a first bump pad on the center region, a second bump pad on the edge region, and a third bump pad on the corner region, a semiconductor chip on the package substrate, the semiconductor chip including a solder bump provided to be electrically connected to the bump pad, and a masking member on the package substrate and covering at least a part of the bump pad, wherein the masking member includes an opening on the corner region that exposes at least a part of the third bump pad.

According to some embodiments of the present disclosure, a semiconductor package may include a package substrate including a center region, an edge region in contact with each side edge of the center region, and a corner region positioned at an end of the edge region, a first bump pad on the center region, a second bump pad on the edge region and having a shape different from that of the first bump pad, a third bump pad on the corner region and having a shape the same as that of the first bump pad, a semiconductor chip including solder bumps coupled onto the package substrate, and a masking member on the package substrate to cover at least a part of the third bump pad, wherein the masking member includes an opening that exposes at least a part of the third bump pad, and the masking member is on the corner region. According to some aspects of the present disclosure, the masking member is disposed in the peripheral region of the package substrate, which can improve a contact defect between the package substrate and the semiconductor chip.

### BRIEF DESCRIPTION OF THE DRAWINGS

FIG. 1 is a diagram illustrating a structure of a semiconductor package and a pattern of warpage.

FIG. 2 is a diagram illustrating a package substrate of a semiconductor package according to some embodiments of the present disclosure.

FIG. 3 is an enlarged view of a region A of FIG. 2.

FIG. 4 is a diagram illustrating a semiconductor package according to some embodiments of the present disclosure.

FIG. 5 is a diagram illustrating a semiconductor package according to some embodiments of the present disclosure.

FIG. 6 is a diagram illustrating a semiconductor package according to some embodiments of the present disclosure.

FIG. 7 is a diagram illustrating a semiconductor package according to some embodiments of the present disclosure.

FIG. 8 is a diagram illustrating a semiconductor package according to some embodiments of the present disclosure.

FIG. 9 is a diagram illustrating a package substrate of a semiconductor package according to some embodiments of the present disclosure.

FIG. 10 is a diagram illustrating a semiconductor package according to some embodiments of the present disclosure.

FIG. 11 is a diagram illustrating a semiconductor package according to some embodiments of the present disclosure.

FIG. 12 is a diagram illustrating a package substrate of a semiconductor package according to some embodiments of the present disclosure.

FIG. 13 is a diagram illustrating a package substrate of a semiconductor package according to some embodiments of the present disclosure.

FIG. 14 is a diagram illustrating a package substrate of a semiconductor package according to some embodiments of the present disclosure.

### DETAILED DESCRIPTION

A semiconductor package according to example embodiments of the present disclosure will be described in detail with reference to the drawings.

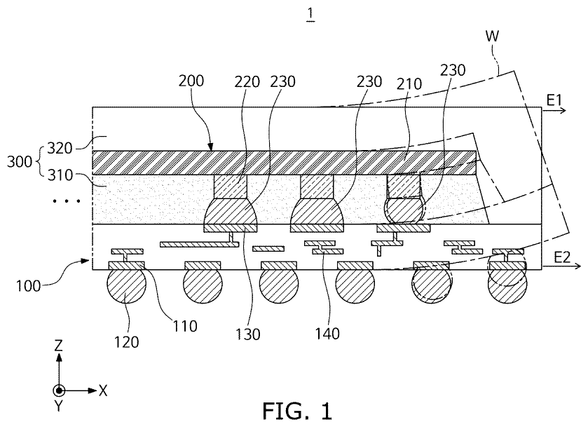

FIG. 1 is a diagram illustrating a structure of a semiconductor package and a pattern of warpage.

There may be a first direction X that may be a horizontal direction, and a second direction Y that may be another horizontal direction intersecting the first direction X. For example, the first direction X and the second direction Y may be directions intersecting each other at right angles. There may be a third direction Z that may intersect both the first direction X and the second direction Y. For example, the third direction Z may be a direction intersecting both the first direction X and the second direction Y at right angles.

Referring to FIG. 1, a semiconductor package 1 may include a package substrate 100, a semiconductor chip 200, a solder bump 230, an underfill 310, a molding layer 320, etc.

The semiconductor chip 200 may be seated on the package substrate 100. It is illustrated herein that only one semiconductor chip 200 is seated on the package substrate 100, but the present disclosure is not limited thereto. For the semiconductor chip 200, a plurality of semiconductor chips 200 with various functions and/or shapes may be arranged on the package substrate 100.

For example, the package substrate 100 may be a printed circuit board or a ceramic substrate. The package substrate 100 will be described herein by way of an example of a printed circuit board (PCB). However, the present disclosure is not limited thereto.

If the package substrate 100 is a PCB, the package substrate 100 may include at least one material selected from phenol resin, epoxy resin, and polyimide. For example, the package substrate 100 may include at least one material selected from FR4, tetrafunctional epoxy, polyphenylene ether, epoxy/polyphenylene oxide, bismaleimide triazine (BT), thermount, cyanate ester, polyimide, and liquid crystal polymer.

The package substrate 100 may include a bump pad 130. The bump pad 130 may be a portion at which the semiconductor chip 200 and the package substrate 100 are electrically connected to each other. The bump pad 130 may be disposed at or on an upper side or surface of the package substrate 100.

The package substrate 100 may further include a ball pad 110. The ball pad 110 may be a portion where a solder ball 120 is in contact with the ball pad 110. The ball pad 110 may be disposed at or on the lower side or surface of the package substrate 100.

An internal wiring 140 electrically connecting the bump pad 130 and the ball pad 110 may be formed within the package substrate 100. The internal wirings 140 each having a separate path may electrically connect the bump pads 130 and the ball pads 110.

The package substrate 100 may further include a wire bonding terminal (not illustrated). It is illustrated herein that the package substrate 100 and the semiconductor chip 200 are electrically connected by the solder bump 230 contacting the bump pad 130. However, the present disclosure is not limited thereto, and the package substrate 100 and the semiconductor chip 200 may be connected by wire bonding.

The bump pad 130, the ball pad 110, and the wire bonding pad (not illustrated) may include at least one of copper, nickel, stainless steel, or beryllium copper. The bump pad 130, the ball pad 110, and the wire bonding pad (not illustrated) may be some of the circuit wirings patterned after Cu foil is coated on the upper and lower sides of the package substrate 100, respectively.

The package substrate 100 according to some embodiments of the present disclosure may be in such a state that the bump pad 130 is open. The upper side of the package substrate 100 may not be covered by a separate configuration such as a solder resist. That is, the patterned circuit wiring may be exposed as it is on the upper side of the package substrate 100. However, the present disclosure is not limited thereto.

A solder resist (SR) may be applied on the lower side of the package substrate 100. The ball pad 110 may be a portion exposed by the solder resist.

The solder ball 120 may be disposed on the lower side of the package substrate 100. The solder ball 120 may be in contact with the ball pad 110. The solder ball 120 may formed be in a downward convex shape. The solder ball 120 may be a part configured to electrically connect the package substrate 100 to another external device.

The semiconductor chip 200 may be a logic semiconductor chip such as a microprocessor. For example, the semiconductor chip 200 may be a central processing unit (CPU), a controller, an application specific integrated circuit (ASIC), etc.

The semiconductor chip 200 may include a wafer chip 210. The solder bump 230 may be disposed on one side or surface of the wafer chip 210. The semiconductor chip 200 may be a flip chip. The semiconductor chip 200 may be disposed on the package substrate 100 such that the solder bump 230 is facing the lower side or surface of the semiconductor chip 200.

The semiconductor chip 200 may include a pillar 220 disposed on one side or surface of the wafer chip 210. The pillar 220 may include copper. The pillar 220 may be a component provided to place the solder bump 230. The solder bump 230 may be disposed on an end of the pillar 220.

A plurality of pillars 220 may be formed. The solder bump 230 may be formed on each pillar 220.

The solder bump 230 may be disposed under the semiconductor chip 200. The solder bump 230 may electrically and physically connect the semiconductor chip 200 to the package substrate 100. In addition, the solder bump 230 may fix the semiconductor chip 200 to the upper side or surface of the package substrate 100.

A plurality of solder bumps 230 may be formed. The plurality of solder bumps 230 may be disposed at predetermined intervals. The intervals between the plurality of solder bumps 230 may vary.

The solder bump 230 may be coupled to the bump pad 130. For example, the solder bump 230 may be a micro solder ball or a solder paste.

The solder bump 230 may be electrically connected to a circuit in the wafer chip 210. That is, circuits inside the wafer chip 210, external devices, etc. may be electrically connected to the package substrate 100 through the solder bump 230.

The semiconductor package 1 may include the underfill 310. The underfill 310 may include an underfill resin such as an epoxy resin, a silica filler, or a flux.

The underfill 310 may be formed by a capillary underfill (CUF) process or a molded underfill process. The underfill 310 formed by the molded underfill (MUF) may be integrated with the molding layer 320 to be described below to form one molding 300.

The underfill 310 may surround the sides or side surfaces of the solder bump 230 and the pillar 220. The underfill 310 may be in or fill a space between the semiconductor chip 200 and the package substrate 100. The underfill 310 may increase adhesive strength between the semiconductor chip 200 and the package substrate 100.

In addition, the underfill 310 may allow other components such as the semiconductor chip 200, the package substrate 100, the solder bump 230, etc. to counteract the deterioration of physical strength due to deformation. For example, the underfill 310 may be a portion configured to remove a space where foreign substances or moisture may penetrate and to prevent electrical migration.

The molding layer 320 may cover all of or a portion of the upper side or surface of the package substrate 100, the side or side surface of the underfill 310, the side or side surface of the semiconductor chip 200, and the upper side or surface of the semiconductor chip 200.

For example, the molding layer 320 may include a silicon-based material, a thermosetting material, a thermoplastic material, a UV treated material, etc. In addition, the molding layer 320 may include a polymer such as a resin, and, for example, may include an epoxy molding compound (EMC).

The molding layer 320 and the package substrate 100 may include materials having different coefficients of thermal expansion. In addition, various components forming the semiconductor package 1 may include materials having various coefficients of thermal expansion. Therefore, the semiconductor package 1 may have different thermal expansion volumes during the reflow process for bonding the solder bump 230 to the bump pad 130.

For example, along the first direction X, the molding layer 320 may undergo a first thermal expansion E1, and the package substrate 100 may undergo a second thermal expansion E2. In this case, the deformation amount of the first thermal expansion E1 may be greater than the deformation amount of the second thermal expansion E2.

As a result, the semiconductor package 1 may generate a warpage W in a downward convex shape. The warpage W occurs due to a difference between the first thermal expansion E1 and the second thermal expansion E2 of FIG. 1, and may make the entire semiconductor package bend. It goes without saying that the shape of the warpage W is illustrative and considers only the molding 300 and the package substrate 100.

The shape of the warpage W illustrated herein is merely an example that considers only the first direction X, and the same pattern of warpage may also occur along the second direction Y. The semiconductor package 1 according to some embodiments of the present disclosure may have a warpage W that is twisted or bent as a whole. Considering many other materials that may be present in the semiconductor package, it is likely that warpage would occur in more complex and varying shapes.

In addition, the degree of deformation of the warpage W may increase toward the edge of the package substrate 100. The contact defects are more likely to occur in the solder bumps 230 closer to the edge portion where the degree of warpage W is the most severe.

Regions closer to the edge of the semiconductor package 1 are more vulnerable to the contact defects caused by the warpage W and the structure for inhibiting or preventing this will be described below.

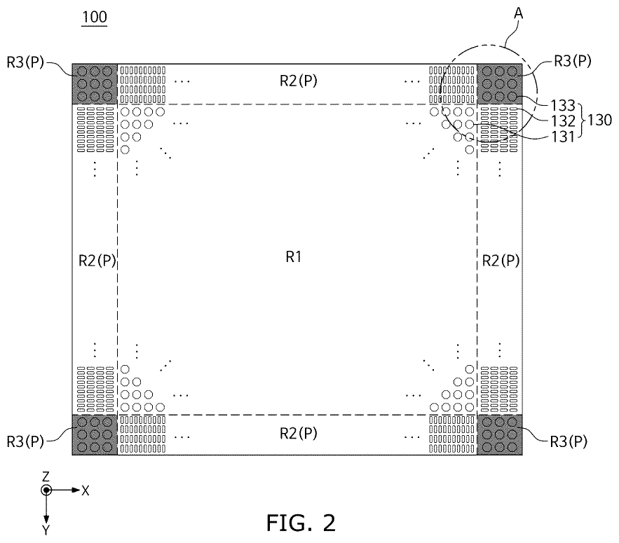

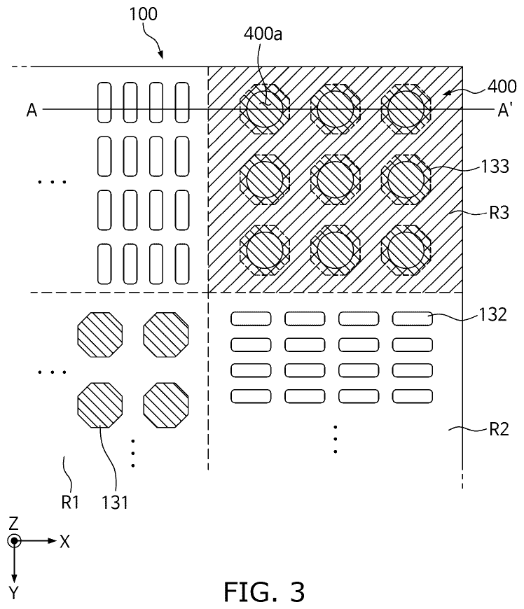

FIG. 2 is a diagram illustrating a package substrate of a semiconductor package according to some embodiments of the present disclosure. FIG. 3 is an enlarged view of a region A of FIG. 2.

The package substrate 100 according to some embodiments of the present disclosure may include a center region R1 and a peripheral region P surrounding the center region R1. That is, the upper side of the package substrate 100 may be divided into the center region R1 and the peripheral region P.

The center region R1 may have a predetermined area in the center of the package substrate 100. The center region R1 may have a rectangular or square shape. The peripheral region P may be the region other than the center region R1 in the package substrate 100.

The peripheral region P may include edge regions R2 contacting each of the edges of the center region R1 and corner regions R3 located at both ends of the edge region R2. The edge region R2 may contact the edge of the package substrate 100 while contacting the edge of the center region R1.

If both the center region R1 and the package substrate 100 have a rectangular or square shape, the edge region R2 may include four regions for each of the edges of the center region R1 and the package substrate 100. Likewise, the corner region R3 may be in contact with both the vertex of the package substrate 100 and the vertex of the center region R1, and there may be four corner regions, one in each vertex of the center region R1 and each vertex of the package substrate 100.

The package substrate 100 may include the bump pad 130 formed on one side.

The bump pad 130 may include a first bump pad 131 formed on the center region R1. The first bump pad 131 may have an octagonal shape. However, this is merely an example, and the shape of the first bump pad 131 is not limited thereto.

The bump pad 130 may include a second bump pad 132 formed on the peripheral region P. The second bump pad 132 may be formed only on the edge region R2. Alternatively, the second bump pad 132 may also be formed on the corner region R3.

The second bump pad 132 may be disposed with a finer pitch than the first bump pad 131. The second bump pad 132 may be formed in a rectangular shape to have a finer pitch than the first bump pad 131. However, the shape of the second bump pad 132 is not limited thereto.

The bump pad 130 may include a third bump pad 133 disposed on the corner region R3. The third bump pad 133 may have a shape different from that of the second bump pad 132. For example, the third bump pad 133 may have the same shape as that of the first bump pad 131. That is, if the first bump pad 131 has an octagonal shape, the third bump pad 133 may also have an octagonal shape.

As described above, the first bump pad 131 and the third bump pad 133 may have areas (e.g., planar areas) similar to or same as each other. By assuming that the volume of the solder bump 230 (see FIG. 1) in contact with the first bump pad 131 and the third bump pad 133 is constant, it will be more likely that the height of the solder bump 230 is kept constant as the areas of the first bump pad 131 and the third bump pad 133 are more similar to each other. That is, after the reflow process, the solder bumps 230 may have similar heights across the center region R1 and the corner region R3.

The package substrate 100 will be described below by referring to FIG. 3 showing an enlarged view of the corner region R3 and the structure around the same.

A masking member 400 may cover at least a part of the bump pad 130. The masking member 400 may include an opening 400a formed to expose at least a part of the bump pad 130.

The masking member 400 may cover a part of the bump pad 130, thereby reducing the area of the bump pad 130 that is exposed. As the exposed area of the bump pad 130 is reduced, an area of the solder bump 230 of the semiconductor chip 200 contacting the bump pad 130 may be reduced.

The masking member 400 may be disposed on the corner region R3 of the package substrate 100. The masking member 400 may cover a part of the third bump pad 133. The masking member 400 may expose another part of the third bump pad 133.

An area (e.g., planar area) of the opening 400a may be smaller than an area (e.g., planar area) of the third bump pad 133. A shape of the opening 400a may be the same as a shape of the third bump pad 133. As illustrated, the opening 400a may have an approximately circular shape. However, the present disclosure is not limited thereto, and the opening 400a may be in any shape as long as it can cover the part of the third bump pad 133 and reduce the area of the solder bump 230 contacting the third bump pad 133. For example, if the third bump pad 133 is in an octagon shape, the opening 400a may also have an octagon shape.

The masking member 400 may include a solder resist. The masking member 400 may be disposed by attaching a patch including the solder resist or applying ink.

A plurality of third bump pads 133 may be disposed. For example, as illustrated, the third bump pads 133 may be arranged in three rows and three columns at predetermined intervals. However, the present disclosure is not limited thereto, and the third bump pads 133 may be arranged in various ways such as by arranging in two rows and two columns.

The masking member 400 may include a plurality of openings 400a corresponding to each of the third bump pads 133. The plurality of openings 400a may expose at least a part of each of the third bump pads 133. That is, the exposed areas of the plurality of third bump pads 133 may be reduced by the plurality of openings 400a.

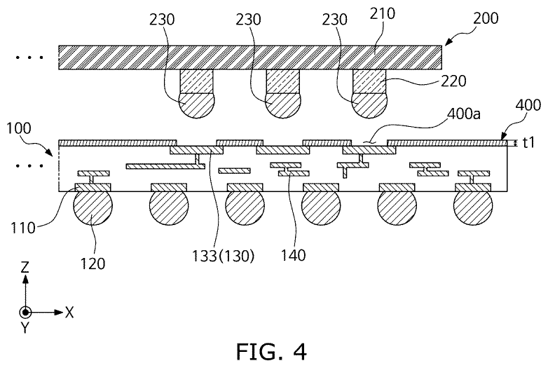

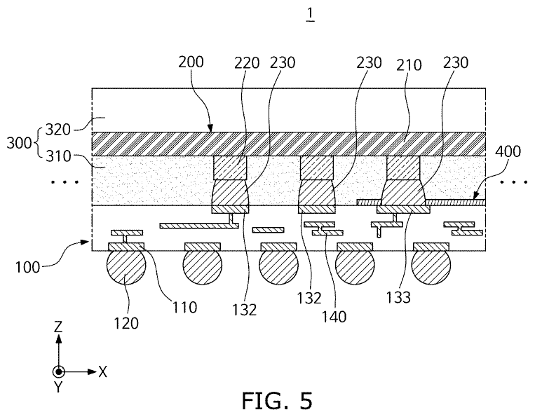

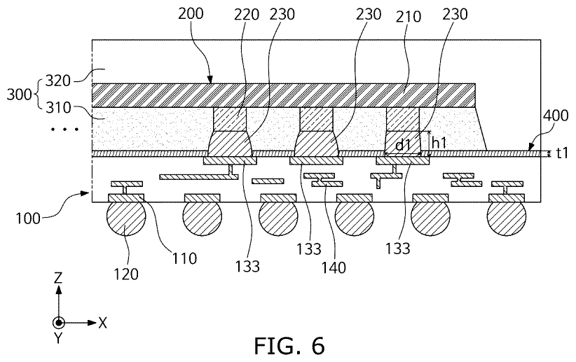

FIG. 4 is a diagram illustrating a semiconductor package according to some embodiments of the present disclosure. FIG. 5 is a diagram illustrating a semiconductor package according to some embodiments of the present disclosure. FIG. 6 is a diagram illustrating a semiconductor package according to some embodiments of the present disclosure. FIGS. 4 to 6 are cross-sectional views illustrating the corner region R3 (see FIG. 3) of the package substrate 100 of the semiconductor package 1 taken along the line A-A′.

Referring to FIG. 4, before the step of seating the semiconductor chip 200 on the package substrate 100, the solder bumps 230 may have a constant volume.

After the semiconductor chip 200 is seated on the package substrate 100, the solder bump 230 may be fused through a reflow process. As a large amount of heat is applied, warpage may occur in the semiconductor chip 200 and the package substrate 100 due to thermal expansion.

As a distance from the center of the semiconductor chip 200 and the package substrate 100 increases, it is more likely that the warpage could occur. That is, the solder bump 230 positioned outside the semiconductor chip 200 may have a non-wetting defect or issue, that is, it is not electrically connected to the bump pad 130. For example, an open failure or short may occur.

Alternatively, the solder bumps 230 positioned in the center of the semiconductor chip 200 may be fused first, and the solder bumps 230 positioned outside the semiconductor chip 200 may not be fused, that is, may have a non-wetting defect or issue.

After the semiconductor chip 200 is seated on the package substrate 100, the solder bump 230 positioned to correspond to the central portion of the semiconductor chip 200, that is, the center region R1 of the package substrate 100, and the solder bump 230 positioned at the portion corresponding to the corner region R3 may have similar volumes.

In this case, the first bump pad 131 of the center region R1 and the third bump pad 133 of the corner region R3 may have similar contact areas with the solder bump 230 because they have the same shape. As a result, the height of the solder bump 230 in the center region R1 may be similar to the height of the solder bump 230 in the corner region R3.

As described above, because the first bump pad 131 of the center region R1 and the third bump pad 133 of the corner region R3 have the same shape, the heights of the solder bumps 230 of the center region R1 and the corner region R3 can be maintained constant.

The semiconductor package 1 according to some embodiments of the present disclosure may include the masking member 400 disposed on the corner region R3 of the package substrate 100.

The masking member 400 may include a solder resist. In addition, the solder resist (SR) may be applied to the lower side or surface of the package substrate 100. The ball pad 110 may be a portion exposed by the solder resist.

Because the masking member 400 is disposed on the upper side or surface of the package substrate 100, it may balance with the solder resist disposed on the lower side. The masking member 400 may include the same solder resist as the solder resist disposed on the lower side of the package substrate 100. That is, the difference in thermal expansion between the upper and lower sides or surfaces of the package substrate 100 may be alleviated during thermal expansion.

In addition, the masking member 400 may include a solder resist having a higher coefficient of thermal expansion than the solder resist disposed on the lower side of the package substrate 100. By forming the solder resist having a higher coefficient of thermal expansion on the upper side or surface of the package substrate 100, it is possible to prevent the warpage of the package substrate 100 from occurring at room temperature. That is, the masking member 400 may serve as a stiffener.

The masking member 400 may cover at least a part of the bump pad 130. The area of the bump pad 130 being exposed may be reduced by the masking member 400. If the volumes of the solder bumps 230 are the same as each other, the area of the solder bump 230 contacting the bump pad 130 may be reduced, thereby ensuring the height of the solder bump 230 after fusing in the reflow process.

Even if a warpage occurs in an area adjacent to the edge of the semiconductor chip 200 and the package substrate 100, because the sufficient height of the solder bump 230 is ensured, it is possible to prevent the non-wetting phenomenon of the solder bump 230.

Referring to FIG. 5, the cross-section of the edge region R2 and the corner region R3 while the semiconductor chip 200 is seated on the package substrate 100 will be described.

The solder bump 230 of the semiconductor chip 200 may be in contact with the second bump pad 132 of the edge region R2 and the third bump pad 133 of the corner region R3. The second bump pad 132 may be positioned closer to the inside of the package substrate 100 than the third bump pad 133.

In this case, it is necessary to consider that the degree of warpage generated on the third bump pad 133 may be more severe. That is, the third bump pad 133 may have a greater probability of a contact defect than the second bump pad 132.

Therefore, it is necessary to reduce the exposed area of the third bump pad 133 by covering with the masking member 400. The exposed area of the third bump pad 133 may be the same as the area of the opening 400a of the masking member 400.

In addition, the masking member 400 may have a predetermined thickness t1 such that the volume occupied by the solder bump 230 in the process of fusion of the solder bump 230 may be limited to the inside of the opening 400a of the masking member 400.

The height of the solder bump 230 fused to the third bump pad 133 may be similar to the height of the solder bump 230 fused to the second bump pad 132. The masking member 400 may limit a contact area of the third bump pad 133 to ensure the height of the solder bump 230. Accordingly, the semiconductor package 1 may prevent a contact defect due to a warpage.

Referring to FIG. 6, the cross-section of the corner region R3 while the semiconductor chip 200 is seated on the package substrate 100 will be described.

The solder bump 230 of the semiconductor chip 200 may be in contact with the third bump pad 133.

The masking member 400 may cover at least a part of the third bump pad 133, thereby limiting an exposed area. The masking member 400 may include a plurality of openings 400a to cover at least a part of each of the third bump pads 133. The plurality of openings 400a may restrict the exposed areas of the third bump pads 133, respectively.

The degree of warpage may be more severe in the third bump pad 133 of the plurality of third bump pads 133, which is adjacent to the edge of the package substrate 100. The contact defect may be more likely to occur in the third bump pad 133 of the plurality of third bump pads 133, which is positioned at an outer side.

Therefore, among the plurality of third bump pads 133, the third bump pad 133 positioned at an outer side may be exposed in a smaller area.

The plurality of openings 400a of the masking member 400 may have various sizes. For example, the opening 400a corresponding to the third bump pad 133 positioned at an outer side may be smaller. That is, the exposed area of the third bump pad 133 positioned at an outer side may be smaller.

It is illustrated herein that the exposed area of the third bump pad 133 positioned at the outermost side is the smallest. That is, a diameter d1 of the exposed area of the third bump pad 133 positioned at the outermost side may be smaller than the diameter of the exposed area of the other third bump pads 133. As a result, a height h1 of the third bump pad 133 positioned at the outermost side may be maintained to be similar to the height of other third bump pads 133.

However, the present disclosure is not limited thereto, and the plurality of openings 400a may be sized such that the third bump pad 133 positioned at an outer side has a smaller area.

Although it is illustrated herein that the masking member 400 is disposed only in the corner region R3, this is merely an example and various arrangements are possible. For example, the masking member 400 may also be disposed in the edge region R2 to partially cover the exposed area of the second bump pad 132.

The size or area of the masking member 400 may vary depending on a method of filling the underfill 310. If the underfill 310 is filled by a capillary underfill (CUF), the size of the masking member 400 may be formed to be 10% or less the size of the semiconductor chip 200. Meanwhile, if the underfill 310 is filled by a molded underfill (MUF), the size of the masking member 400 may be variously provided.

According to the semiconductor package 1 according to some embodiments of the present disclosure, by forming the masking member 400 on the corner region R3, it is possible to prevent a contact defect that may occur between the semiconductor chip 200 and the package substrate 100.

The semiconductor package according to other embodiments will be described below. The same or similar configurations will be given the same reference numerals, and detailed description thereof may be omitted in the interest of brevity.

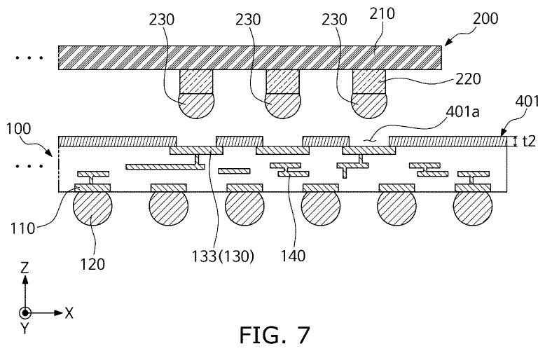

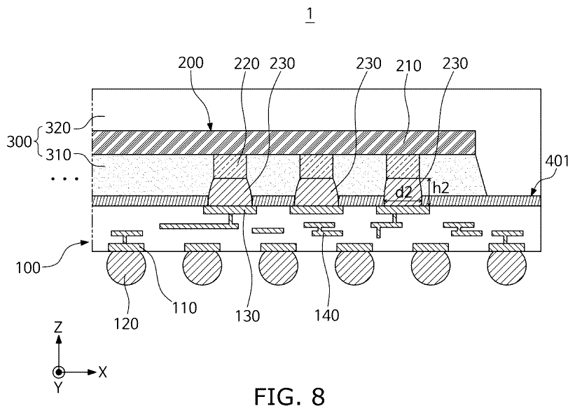

FIG. 7 is a diagram illustrating a semiconductor package according to some embodiments of the present disclosure. FIG. 8 is a diagram illustrating a semiconductor package according to some embodiments of the present disclosure.

Referring to FIGS. 7 and 8, a masking member 401 may have a predetermined thickness t2. The thickness t2 of the masking member 401 may be greater than the thickness t1 of the masking member 400 described above in FIG. 6.

The volume occupied by the solder bump 230 in the process of fusion of the solder bump 230 may be limited to the inside of an opening 401a of the masking member 401. As the thickness t2 of the masking member 401 increases, the volume occupied by the solder bump 230 may be further limited. That is, the solder bump 230 may not flow out of the opening 401a of the masking member 401 during the fusion process. The area occupied by the solder bump 230 may be limited by the opening 401a, thereby ensuring the height occupied by the solder bump 230 after fusion.

It is illustrated that the masking member 401 of the present disclosure is a single layer having the thickness t2, but the present disclosure is not limited thereto. The masking member 401 may include several layers such as a first masking layer, a second masking layer, etc. with smaller thicknesses.

In addition, the masking member 401 may have different heights according to a position. The thickness of the masking member 401 may increase as the third bump pad 133 is closer to the edge of the package substrate 100.

The thickness t2 of the masking member 401 may have various values, although it may preferably be an appropriate value in consideration of a process of forming the underfill 310.

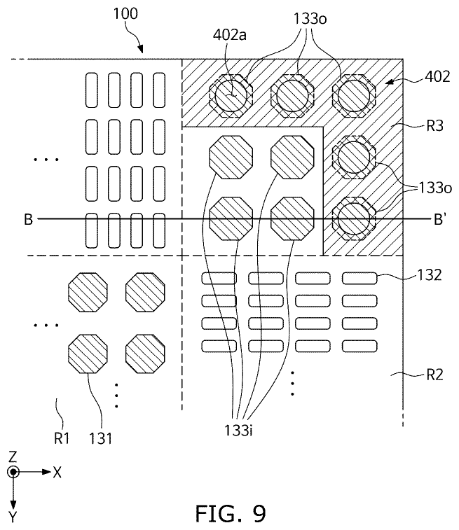

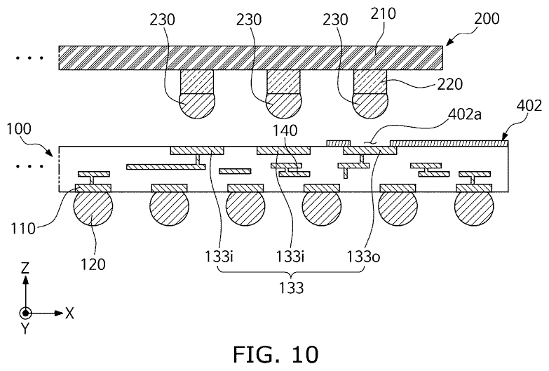

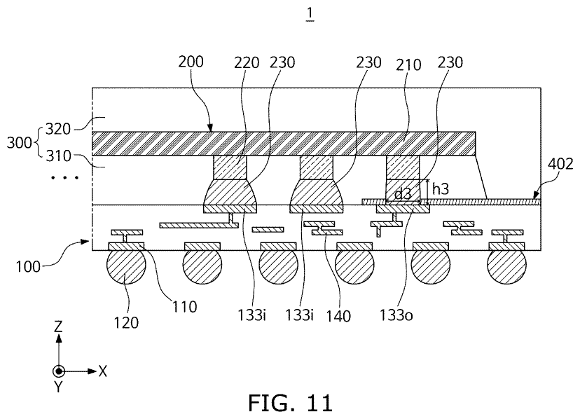

FIG. 9 is a diagram illustrating a package substrate of a semiconductor package according to some embodiments of the present disclosure. FIG. 10 is a diagram illustrating a semiconductor package according to some embodiments of the present disclosure. FIG. 11 is a diagram illustrating a semiconductor package according to some embodiments of the present disclosure.

Referring to FIGS. 9 to 11, the package substrate 100 according to some embodiments of the present disclosure may include the plurality of third bump pads 133 formed in the corner region R3. FIGS. 10 to 11 are cross-sectional views illustrating the corner region R3 (see FIG. 9) of the package substrate 100 of the semiconductor package 1 taken along the line B-B′ of FIG. 9.

The plurality of third bump pads 133 may include an outer pad 1330 disposed along the edge of the package substrate 100. The outer pad 1330 may refer to be adjacent the edge of the package substrate. The outer pad 1330 may refer to the outermost pad of the plurality of third bump pads 133. Alternatively, the outer pad 1330 may refer to, among the plurality of third bump pads 133, a configuration that has the shortest linear distance away from the edge of the package substrate 100.

The plurality of third bump pads 133 may include an inner pad 133i positioned inside the package substrate 100 than the outer pad 1330. The inner pad 133i may refer to a pad positioned farther from the edge of the package substrate 100 than the outer pad 1330. The inner pad 133i may refer to a pad positioned closer to the center region R1 of the package substrate 100 than the outer pad 1330. That is, the pads positioned in the center of the plurality of third bump pads 133 shown in FIG. 9 may be the inner pads 133i.

However, this is merely an example, and the same may apply when the plurality of third bump pads 133 are arranged in two rows and two columns. In this case, the plurality of third bump pads 133 may include three outer pads 1330 and one inner pad 133i.

In addition, the plurality of third bump pads 133 may be configured with a larger number of bump pads, and the above description may also apply even when they are randomly arranged.

A masking member 402 may be disposed along the outer pads 1330. The masking member 402 may be disposed along only the outer pads 1330 and not the inner pad 133i. Because the outer pads 1330 are disposed along the edge of the package substrate 100, the masking member 402 may also be disposed along the edge of the package substrate 100.

The masking member 402 may include an opening 402a formed to expose at least a part of the outer pad 1330. If a plurality of outer pads 1330 are formed, a plurality of openings 402a may also be formed to correspond to the outer pads 1330.

As described above, warpage and contact defect are likely to occur in the outer pad 1330. Accordingly, the masking member 402 may be placed to cover at least a part of the outer pad 1330.

The opening 402a of the masking member 402 may limit the exposed area of the outer pad 1330. By limiting the exposed area of the outer pad 1330, the area or diameter of the solder bump 230 in contact with the outer pad 1330 may be reduced. As a result, it is ensured that the solder bump 230 after fusing has a height h3 as the height of the other solder bumps 230.

As described above, the masking member 402 may prevent the contact defects from occurring in the outer pads 1330 formed along the edge of the package substrate 100.

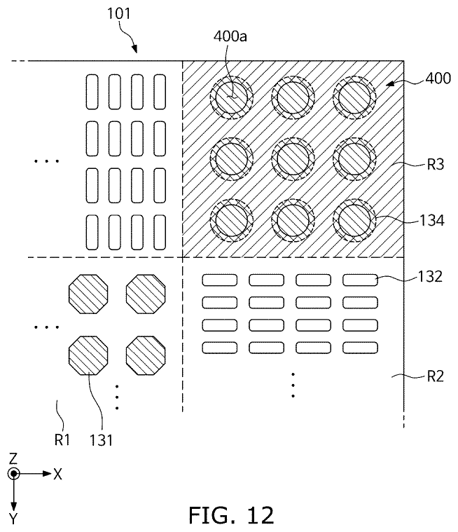

FIG. 12 is a diagram illustrating a package substrate of a semiconductor package according to some embodiments of the present disclosure.

A package substrate 101 according to some embodiments of the present disclosure may include a third bump pad 134 formed in the corner region R3.

The third bump pad 134 may have a shape different from that of the second bump pad 132. The third bump pad 134 may have a shape different from that of the first bump pad 131.

The third bump pad 134 may have an approximately circular shape. However, the present disclosure is not limited thereto, and the third bump pad 134 may be formed in various shapes such as an ellipse, a semicircle, a fan shape, etc.

The third bump pad 134 may have an area (e.g., planar area) that is the same as or similar to the area of the first bump pad 131. Accordingly, even the third bump pad 134 formed in any other shape may also be prevented from the contact defect when the semiconductor chip 200 is seated on the package substrate 101.

Specifically, it can be considered that the area of the third bump pad 134 is similar to the area of the first bump pad 131, if the height of the solder bumps 230 fused to the third bump pad 134 and the height of the solder bumps 230 fused to the first bump pad 131 are kept similar, preventing the contact defects from occurring.

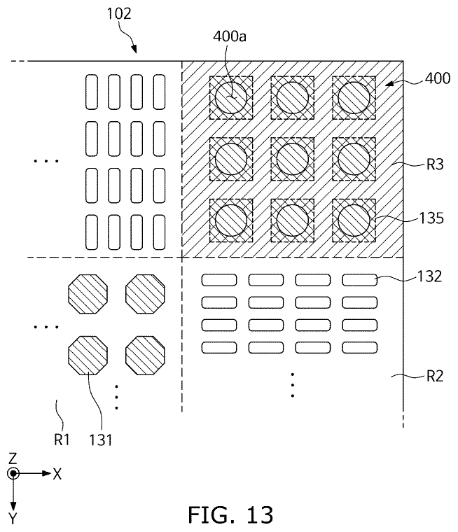

FIG. 13 is a diagram illustrating a package substrate of a semiconductor package according to some embodiments of the present disclosure.

A package substrate 102 according to some embodiments of the present disclosure may include a third bump pad 135 formed in the corner region R3.

The third bump pad 135 may have a shape different from that of the second bump pad 132. The third bump pad 135 may have a shape different from that of the first bump pad 131.

The third bump pad 135 of the present disclosure may have an approximately rectangular shape. However, the present disclosure is not limited thereto, and the shape of the third bump pad 135 may be formed in various shapes such as a square, a rectangle, a trapezoid, etc. In addition, the third bump pad 135 may be provided in various other polygonal shapes.

Likewise, a third bump pad 135 may have an area that is the same as or similar to an area of the first bump pad 131. Accordingly, even the third bump pad 135 formed in any other shape may also be prevented from the contact defect when the semiconductor chip 200 is seated on the package substrate 101.

Specifically, it can be considered that the area of the third bump pad 135 is similar to the area of the first bump pad 131, if the height of the solder bumps 230 fused to the third bump pad 135 and the height of the solder bumps 230 fused to the first bump pad 131 are kept similar, preventing the contact defects from occurring.

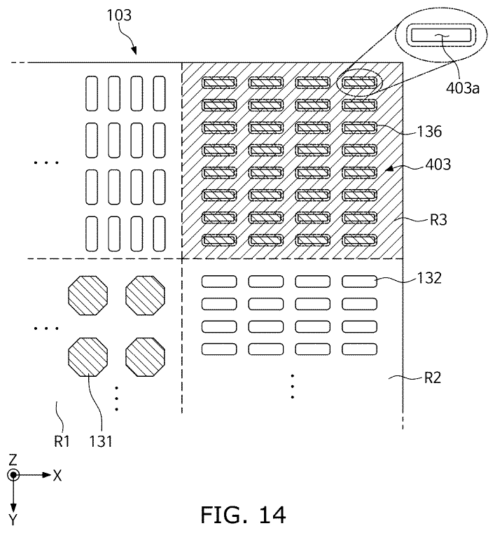

FIG. 14 is a diagram illustrating a package substrate of a semiconductor package according to some embodiments of the present disclosure.

A package substrate 103 according to some embodiments of the present disclosure may include a third bump pad 136 formed in the corner region R3.

The third bump pad 136 may have the same shape as that of the second bump pad 132. The third bump pad 136 may have the same shape as that of the second bump pad 132 for fine pitches of the edge region R2 and the corner region R3 of the package substrate 103.

The second bump pad 132 and the third bump pad 136 of the present disclosure may have an approximately rectangular shape. However, the present disclosure is not limited thereto, and the second bump pad 135 and the third bump pad 136 may be provided in various shapes and have a certain aspect ratio or higher so as to be arranged at fine intervals.

The second bump pads 132 may have a rectangular shape so as to be disposed at a fine interval. Like the second bump pad 132, the third bump pad 136 may also have a rectangular shape. In this case, the corner of the rectangle may be rounded or chamfered. However, the present disclosure is not limited thereto.

The third bump pad 136 may have a shape different from that of the first bump pad 131. The third bump pad 136 may have a smaller area than the first bump pad 131.

In this case, the solder bump 230 may be disposed such that the volume thereof in contact with the third bump pad 136 may be small. Because the amount of the solder bump 230 is smaller, it is more likely that the non-wetting issue may occur. Therefore, a masking member 403 may be provided to prevent this.

The masking member 403 may be placed to cover at least a part of the third bump pad 136. The masking member 403 may include an opening 403a to expose the other part of the third bump pad 136.

The masking member 403 may limit a contact area between the third bump pad 136 and the solder bump 230 to ensure the height of the solder bump 230 contacting the third bump pad 136.

Certain example embodiments of the present disclosure have been described above for purposes of illustration only, and those having ordinary skill in the art will be able to make various modifications, changes and additions within the spirit and scope of the present disclosure, and such modifications, changes and additions should be construed to be included in a scope of the claims.

What is claimed is:

1. A semiconductor package comprising:
a package substrate including a center region and a peripheral region surrounding the center region;
a bump pad including a first bump pad on the center region and a second bump pad on the peripheral region and having a planar shape different from that of the first bump pad;
a semiconductor chip on the package substrate and including a solder bump electrically connected to the bump pad; and
a masking member on the package substrate to cover at least a part of the bump pad,
wherein the peripheral region includes an edge region in contact with each edge of the center region and corner regions positioned at both ends of the edge region, and
the masking member is on the corner regions.

2. The semiconductor package according to claim 1, wherein the second bump pad is on the edge region, and
the bump pad further includes a third bump pad on the corner regions and having a shape different from that of the second bump pad.

3. The semiconductor package according to claim 2, wherein the masking member includes an opening that exposes at least a part of the third bump pad.

4. The semiconductor package according to claim 2, wherein the first bump pad and the third bump pad have the same shape as each other.

5. The semiconductor package according to claim 3, wherein the opening has a smaller area than an area of the third bump pad.

6. The semiconductor package according to claim 5, wherein the third bump pad comprises a plurality of third bump pads, and
the masking member includes a plurality of openings corresponding to each of the plurality of third bump pads.

7. The semiconductor package according to claim 2, wherein the third bump pad includes an outer pad adjacent an edge of the package substrate and an inner pad positioned farther away from the edge of the package substrate than the outer pad, and
the masking member extends only along the outer pad.

8. The semiconductor package according to claim 7, wherein the masking member includes an opening that exposes at least a part of the outer pad.

9. The semiconductor package according to claim 1, wherein the masking member includes a solder resist.

10. The semiconductor package according to claim 1, wherein the first bump pad has an octagonal shape and the second bump pad has a rectangular shape.

11. A semiconductor package comprising:
a package substrate including a center region, an edge region in contact with each edge of the center region, and a corner region at an end of the edge region;
a bump pad including a first bump pad on the center region, a second bump pad on the edge region, and a third bump pad on the corner region;
a semiconductor chip on the package substrate, the semiconductor chip including a solder bump provided to be electrically connected to the bump pad; and
a masking member on the package substrate and covering at least a part of the bump pad,
wherein the masking member includes an opening on the corner region that exposes at least a part of the third bump pad.

12. The semiconductor package according to claim 11, wherein the third bump pad has a shape different from that of the second bump pad and a shape same as that of the first bump pad.

13. The semiconductor package according to claim 11, wherein the opening has a smaller area than an area of the third bump pad.

14. The semiconductor package according to claim 13, wherein the third bump pad comprises a plurality of third bump pads, and
the masking member includes a plurality of openings corresponding to each of the plurality of third bump pads.

15. The semiconductor package according to claim 13, wherein the third bump pad includes an outer pad adjacent an edge of the package substrate and an inner pad positioned closer to the center region than is the outer pad, and
the masking member extends only along the outer pad.

16. The semiconductor package according to claim 15, wherein the masking member includes an opening that exposes at least a part of the outer pad.

17. The semiconductor package according to claim 11, wherein the masking member includes a solder resist.

18. The semiconductor package according to claim 17, wherein the solder resist has a higher coefficient of thermal expansion than that of the package substrate.

19. A semiconductor package comprising:
a package substrate including a center region, an edge region in contact with each side edge of the center region, and a corner region positioned at an end of the edge region;
a first bump pad on the center region;
a second bump pad on the edge region and having a shape different from that of the first bump pad;
a third bump pad on the corner region and having a shape the same as that of the first bump pad;
a semiconductor chip including solder bumps coupled onto the package substrate; and
a masking member on the package substrate to cover at least a part of the third bump pad,
wherein the masking member includes an opening that exposes at least a part of the third bump pad, and the masking member is on the corner region.

20. The semiconductor package according to claim 19, wherein the opening has a smaller area than an area of the third bump pad.
